(19) United States
(12) Patent Application Publication
(10) Pub. No.: US 2005/0146366 A1
(43) Pub. Date: Jul. 7, 2005

(54) High-resolution digital pulse width modulator and method for generating a high-resolution pulse width modulated signal

(75) Inventor: Andreas Steinschaden, Riegersdorf (AT)

Correspondence Address: Maginot, Moore & Beck, Bank One Tower, 111 Monument Circle, Suite 3000, Indianapolis, IN, 46204, US

(73) Assignee: Infineon Technologies AG, Munchen (DE)

(21) Appl. No.: 10/998,177

(22) Filed: Nov. 24, 2004

(30) Foreign Application Priority Data
Nov. 27, 2003 (DE) 103 55 320.7

(51) Int. Cl. H03K 3/017

(52) U.S. Cl. 327/175

(57) ABSTRACT

High-resolution digital pulse width modulator having a digital pulse width modulator unit for receiving a clock signal and for receiving first bits of a digital control signal in order to generate a first pulse width modulated intermediate signal whose pulse width is an integral multiple of the clock period, having a programmable signal delay path for delaying the first intermediate signal by a programmable delay time on the basis of second bits of the digital control signal and for outputting at least one pulse width modulated intermediate signal, the signal delay time being synchronized with the clock signal, and having a logic circuit for logically combining the intermediate signals and outputting them to form a pulse width modulated output signal.

High-resolution digital pulse width modulator and method for generating a high-resolution pulse width modulated signal

The present invention relates to a high-resolution digital pulse width modulator and also to a method for generating a high-resolution pulse width modulated signal.

Pulse width modulators are used to drive DC sources and provide a turn-on time and a turn-off time within a particular switching period. Pulse width modulation is effected by changing the ratio of the turn-on time to the turn-off time. When driving DC sources, an extended turn-on time provides a greater arithmetic mean value for the output voltage and thus a greater output current. Pulse width modulated signals may also be used for message transmission or may constitute engine controllers in automotive technology, for example.

In a similar design, a pulse width modulated signal can be generated by comparing a triangular-wave voltage at a constant frequency with a variable DC control voltage. If the control voltage is greater than the instantaneous value of the triangular-wave voltage, a high signal, for example, is present at the output of a comparator which compares the control voltage with the instantaneous value of the triangular-wave voltage. If the instantaneous value of the triangular-wave voltage rises above the value of the control voltage, the comparator provides a low signal. The turned-on duration is thus dependent on the DC control voltage at a fixed frequency which is determined by the triangular-wave voltage.

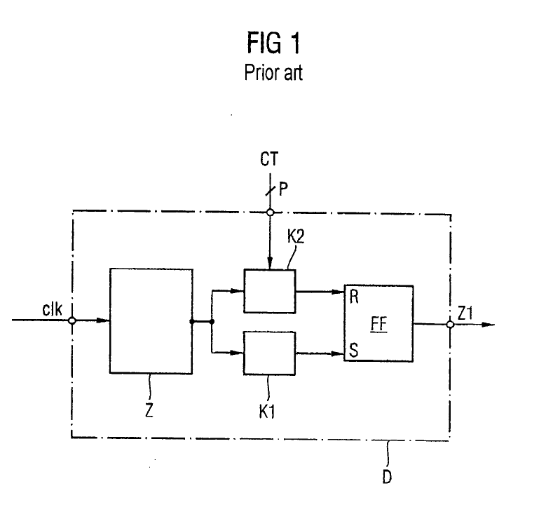

FIG. 1 shows a pulse width modulator unit of digital design. The digital pulse width modulator unit D has a counter Z for receiving a clock signal clk, the output of said counter being coupled to a first comparator K1 and to a second comparator K2, and the outputs of the comparators K1, K2 controlling the Set and Reset inputs of an RS flip-flop FF. The RS flip-flop FF provides a pulse width modulated signal Z1 at the output. The first comparator K1 compares the counter signal with an initialization value for the counter, for example zero, and provides the flip-flop FF with a Set signal. The second comparator K2 compares the counter signal with a digital control signal CT (which has the same bit length P as the counter) and provides the flip-flop FF with a Reset signal when the counter value corresponding to the control signal CT is exceeded. The digital pulse width modulator D based on the prior art thus provides, at the output, a pulse width modulated signal Z1 whose pulse width is a multiple of the clock period of the clock signal clk. In this case, the multiple is prescribed by the control signal which has a length of P bits.

In the case of digitally controlled pulse width modulators based on the prior art, the pulse width of the pulse width modulated signal is possible only in steps of the clock frequency. An increased resolution can be achieved, for example, only at an internally multiplied clock frequency. However, an increased clock frequency is not always available and it is necessary to operate at the clock frequency as the basic unit. If digital pulse width modulators having an excessively low resolution, i.e. too much quantization between controllable pulse widths, are used in control loops, this may lead to subharmonic oscillations in control loops and may give rise to instabilities. If digital pulse width modulators having only a low resolution are used as digital/analog converters, this causes severe signal noise.

A circuit arrangement for a digital pulse width modulator is described in B. Patella, A. Prodic, A. Zirger and D. Maksimovic, “High-frequency digital controller IC for DC-DC converters”, IEEE Transactions on Power Electronics, January 2003. In this case, a ring oscillator comprising resettable flip-flops—which act as delay stages—generates a system clock signal. Clock signals which have been delayed or phase-shifted to varying degrees are tapped off between the flip-flops or delay stages by means of a multiplexer and are routed to a logic circuit. The latter uses an RS flip-flop to generate pulse width modulated signals from the system clock (which has been generated) and the phase-shifted clock signals.

In the case of a clock period which is predetermined by the properties of the flip-flops used in the ring oscillator, a circuit arrangement of this type allows pulse width modulation operations with pulse widths which can be changed in parts of the system clock period in accordance with the delay times of the flip-flops.

However, the fixed design of the flip-flops or delay stages and the generation of the system clock in the pulse width modulator itself make it possible to synchronize with an external clock signal only when there is exactly one system clock. In addition, the delay time per delay stage—and thus the system clock—depends on fluctuations in the operating temperature, in the supply voltage or on transistor parameters during production. This leads to mixed frequency products in adjacent telecommunications circuit parts, for example in mobile telephones which are used in a plurality of frequency bands (dual-band or tri-band phones). After being demodulated, said mixed frequency products generate interfering singing noises in the useful signal (for example in a voice signal). In digital control loops, a low system clock rate produces a greater phase rotation of the control loop's transfer function and thus a smaller phase margin for the control loop. This reduces attenuation and may thus lead to undesirable natural oscillations in the control loop. However, in circuit arrangements based on the prior art, high clock frequencies can disadvantageously be achieved only by means of hardware changes or new development. Rather, a device for pulse width modulation is required, said device operating in a stable manner at high and variable (external) clock frequencies.

Therefore, it is an object of the present invention to provide a high-resolution digital pulse width modulator and a method for generating a high-resolution pulse width modulated signal, which modulator can be used at various external clock frequencies and is robust toward fluctuations in the operating temperature, supply voltage or production parameters.

According to the invention, this object is achieved by means of a high-resolution digital pulse width modulator having the features of patent claim 1 and also by means of a method for generating a high-resolution pulse width modulated signal having the method steps claimed in patent claim 21.

Accordingly, a high-resolution digital pulse width modulator is provided, said modulator having a digital pulse width modulator unit for receiving a clock signal having a clock period T and for receiving first M bits of a digital control signal of bit length P=M+N in order to generate a first pulse width modulated intermediate signal whose pulse width is an integral multiple of the clock period T. The digital pulse width modulator also has a programmable signal delay path for delaying the first intermediate signal by a programmable signal delay time At on the basis of the second N bits of the digital control signal and for outputting at least one second pulse width modulated intermediate signal, the signal delay time At and the clock period T of the clock signal having a fixed ratio. In addition, a logic circuit for logically combining the intermediate signals and outputting them to form a pulse width modulated output signal is provided.

The inventive method for generating a high-resolution pulse width modulated signal has the following method steps:

(a) a clock signal having a clock period T is received;

(b) a first pulse width modulated intermediate signal whose pulse width is a multiple of the clock period T is generated;

(c) a signal delay time At is determined, so that a multiple of the delay time At is equal to the clock period T;

(d) at least one second intermediate signal is generated by delaying the first intermediate signal by the particular signal delay time At;

(e) the first intermediate signal is logically combined with the second intermediate signal in order to generate the pulse width modulated output signal.

The idea on which the present invention is based involves branching off a pulse width modulated signal from a pulse width modulator unit and delaying it in such a manner that the maximum delay time is exactly one clock period. This “synchronization” or control of the delay time on the basis of the clock signal's clock period makes it possible to operate the inventive high-resolution digital pulse width modulator at various clock frequencies.

The resolution of the pulse width modulation results from the difference between various delay times in the signal delay path, the maximum delay time (which is composed of various delay stages) always being exactly one clock period, however. This has the advantage that pulse widths having an interval of time that is shorter than one clock period can also be controlled. In addition, on account of the synchronization or adjusting mechanism, the high-resolution digital pulse width modulator is insensitive to production-dependent fluctuations or changes in temperature which affect the delay path.

In one preferred embodiment, the logic circuit is an OR gate or a flip-flop.

Another preferred embodiment of the inventive pulse width modulator provides a control logic unit which receives the clock signal and provides the signal delay path with at least one adjusting signal or control signal. The control logic unit advantageously uses the clock signal to control the delay path in such a manner that, in arbitrary circumstances, for example changes in temperature, voltage fluctuations or fluctuations in the clock rate, the ratio of the delay times to the clock period T applied clock signal is always fixed.

In accordance with another preferred embodiment of the inventive pulse width modulator, the signal delay path has controllable delay stages which are controlled by the adjusting signal or control signal. The delay stages are controlled in a particularly advantageous manner in such a way that an integral multiple of the delay time Δt of at least one delay stage is equal to the clock period T of the clock signal or else that the sum of the delay times of the delay stages is equal to the period duration T of the clock signal. If the delay stages are controlled in accordance with this preferred embodiment, the delay times and the clock period T of the clock signal always have the same ratio with respect to one another, and the delay times may be controlled in arbitrary stages in accordance with the delay times of the delay stages.

In another particularly preferred embodiment, the delay stages are connected in series, and the second intermediate signals can be tapped off between the delay stages. In addition, the signal delay path preferably has a multiplexer which switches through one of the second control signals to the logic circuit on the basis of the second N bits of the digital control signal. It is extremely advantageous if exactly 2^{N}−1 delay stages are provided, because the representational space for the N bits is thus converted, in the best possible manner, into delay times.

In one preferred development of the inventive pulse width modulator, the control logic unit has a delay locked loop. The latter preferably contains 2^{N} controllable delay stages which are connected in series and are all of identical design. The delay locked loop also has a phase detector which compares the clock signal with the clock signal which has passed through the delay stages in the delay locked loop and outputs a comparison result to a filter. The filter, which is preferably digital, advantageously provides the delay stage in the delay locked loop and the delay stages in the delay path with the adjusting signal or control signal. The use of a delay locked loop has the advantage that recourse can be had to standard modules, and simple connection in accordance with the design of the inventive high-resolution digital pulse width modulator is possible.

The invention is explained in more detail below with reference to the exemplary embodiments which are indicated in the schematic figures of the drawing, in which:

FIG. 1: shows a pulse width modulator based on the prior art;

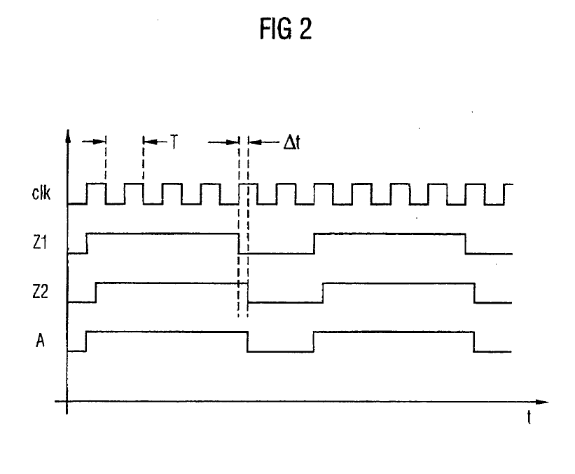

FIG. 2: shows the clock, intermediate and output signals of the inventive pulse width modulator;

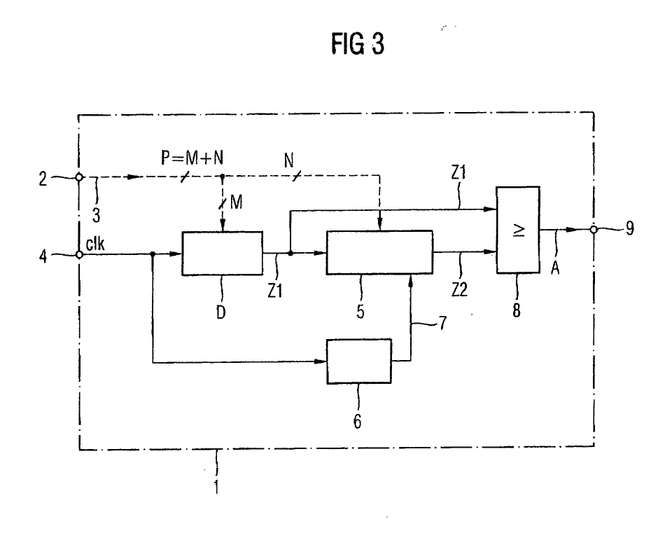

FIG. 3: shows a block diagram of the inventive pulse width modulator; and

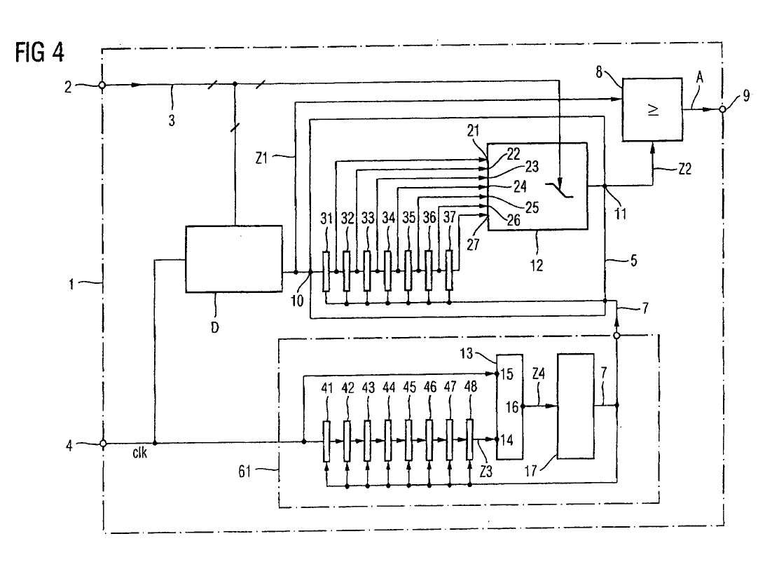

FIG. 4: shows one preferred embodiment of the inventive pulse width modulator.

Unless indicated otherwise, elements which are the same or have the same function are provided with the same reference symbols in all of the figures of the drawings.

FIG. 2 shows a clock signal clk having the clock period T and a first pulse width modulated intermediate signal Z1 whose pulse width is a multiple of the clock period T. According to the invention, the first intermediate signal Z1 is provided by a pulse width modulator unit D based on the prior art. The second intermediate signal Z2, which is produced from the first intermediate signal Z1 (which has been delayed by a delay time Δt), is furthermore indicated. In this special case, the clock signal clk is used to control the delay time Δt in such a manner that the delay time Δt is exactly one quarter of the clock period T. Logically combining the two intermediate signals Z1 and Z2, for example by means of a logic OR function, generates the output signal A, which has a rising edge which is identical to the rising edge of the first intermediate signal Z1, the falling edge of the output signal A being identical to the falling edge of the second intermediate signal Z2.

FIG. 3 shows a block diagram of the inventive high-resolution pulse width modulator 1 having a first input 2 for receiving a digital control signal 3 of bit length P=M+N and a second input 4 for receiving the clock signal clk. A digital pulse width modulator unit D which receives the clock signal clk and also first M bits of the digital control signal 3 is provided. The digital pulse width modulator unit D provides, at the output, a pulse width modulated intermediate signal Z1 which is received by a programmable delay path 5, is delayed by a programmable delay time Δt and is available as a second intermediate signal Z2. The programmable delay path 5 also receives second N bits of the digital control signal CT and delays the first intermediate signal Z1 with respect to the second intermediate signal Z2 on the basis of these N bits. A control logic unit 6 which receives the clock signal clk and provides the programmable signal delay path 5 with an adjusting signal 7 as control signal is furthermore provided. An OR gate 8 receives the first intermediate signal Z1 and the second intermediate signal Z2 and combines these two intermediate signals to form the output signal A which is applied to an output 9.

The control logic unit 6 uses a control signal 7 to control the programmable delay path 5 in such a manner that the delay time Δt amounts, in stages, to up to one clock period T. The second N bits of the digital control signal 3 control the programmable delay path 5 in such a manner that a delay time Δt of between zero and, at most, the clock period T is generated in accordance with the bit combination.

FIG. 4 shows one preferred embodiment of the inventive high-resolution digital pulse width modulator 1. The high-resolution digital pulse width modulator 1 has a first input 2 for receiving a digital control signal 3 of bit length P=M+N, the most significant M bits being routed as a control signal to a digital pulse width modulator unit D. The least significant N bits of the digital control signal 3 are routed as a control signal to a programmable signal delay path 5.

The inventive high-resolution digital pulse width modulator 1 also has a second input 4 for receiving a clock signal clk which is routed to the digital pulse width modulator unit D and to a delay locked loop (DLL) 61. The DLL 61 is used as a control logic unit for the programmable delay path 5 and outputs a control signal 7 to the latter.

In accordance with the first M bits of the digital control signal 3, the digital pulse width modulator unit D provides a pulse width modulated intermediate signal Z1 which is routed to an input 10 of the programmable delay path 5. Δt an output 11, the programmable delay path 5 provides a second intermediate signal Z2 which has been delayed by a particular delay time Δt with respect to the first intermediate signal Z1 provided by the digital pulse width modulator unit D.

The two intermediate signals Z1, Z2 are logically combined, by means of an OR gate 8, to form a pulse width modulated output signal A which is applied to an output 9 of the inventive high-resolution digital pulse width modulator 1.

The programmable delay path 5 has a multiplexer 12 having seven inputs 21-27, seven delay stages 31—37 being connected in series between the input 10 of the programmable delay path 5 and a first input 27 of the multiplexer 12. Nodes which are connected, via lines, to the remaining six inputs 21-26 of the multiplexer are provided between the delay stages 31-37. In accordance with the least significant N bits of the digital control signal 3, the multiplexer 12 switches through one of the signal present at its inputs 21-27 to the output 11 of the programmable delay path 5 as a second intermediate signal Z2.

The controllable delay stages 31-37 are controlled by an adjusting signal 7 provided by the delay locked loop 61.

The delay locked loop 6 has eight identical controllable delay stages 41-48 which are connected in series between a first input 14 of a phase detector 13. The phase detector 13 in the DLL 61 compares the clock signal Z3, which passes through all of the delay stages 41-48, with the undelayed clock signal clk, which is applied to a second input 15 of the phase detector 13, and provides an output 16 with a comparison result Z4. The output signal Z4 from the phase detector 13 is routed to a counter 17 which returns an analog adjusting signal 7 in a control loop to the delay stages 41-48 in the delay locked loop 6.

In addition, the adjusting signal 7 is coupled to the delay stages 31-37 in the programmable delay path 5. The delay stages 31-37, 41-48 in the programmable delay path 5 and in the delay locked loop 61 are of identical design, for example in the form of controllable inverters whose delay time is set by means of a control voltage. In the present embodiment of the high-resolution digital pulse width modulator 1, the adjusting signal 7 provided by the delay locked loop 61 is used as a control signal for the controllable delay-stages 31-37, 41-48.

The clock signal clk is used to control or adjust the delay times of the programmable delay path 5 in such a manner that an integral multiple of the delay time Δt of a delay stage 31-37, 41-48 is equal to the clock period T of the clock signal clk. In the present embodiment, the delay locked loop 61 contains eight delay stages 41-48 through which the signal clk passes and is routed, as an intermediate signal Z3, to the phase detector 13, which provides the adder 17 with a signal Z4 until the delayed clock signal Z3 and the clock signal clk are in phase. As long as the phases do not match, the adder 7 provides the delay stages 41-48 with a rising adjusting signal 7, as a result of which the delay times Δt of said delay stages are changed. If the phases of the clock signal clk and the intermediate signal Z3 match, the DLL 61 locks the value of the adjusting signal 7 and thus the delay times of the delay stages 31-37, 41-48. All of the delay stages 31-37, 41-48 in the programmable delay path 5 and in the DLL 61 are now set in such a manner that an integral multiple of the delay time Δt of a delay stage 31-37, 41-48 is exactly equal to the clock period T of the clock signal clk.

In the present preferred embodiment, N=3 bits are provided for the purpose of driving the multiplexer 12 in the programmable delay path 5. Pulse width modulation is thus possible in steps of one eighth of the clock period T of the clock signal clk. This high-resolution pulse width modulation is independent of the frequency of the clock signal clk because the delay locked loop 61 which is used as the control logic unit automatically adapts the delay times Δt of the identical delay stages 31-37 used in the programmable delay path 5.

Although the present invention has been explained above with reference to one preferred exemplary embodiment, it is not restricted thereto but rather can be modified multifariously.

The invention is not restricted to the special design (shown in FIG. 4 above) of the delay locked loop 61 or of the controllable delay stages 31-37, 41-48.

The control logic unit 61 which is used to adjust the delay stages can also be designed in an alternative manner, for example as a phase locked loop, without departing from the fundamental principle of automatic adjustment using the undelayed clock signal clk.

In particular, the programmable delay path may have a register chain comprising, for example, flip-flops which are controlled by one or more synchronization signals, the synchronization or adjusting signals being generated by a phase locked loop. In this case, the external clock signal passes through the phase locked loop, whose internal synchronization signals are also routed to the register chain.

The delayed or phase-shifted clock signal may be combined with the original clock signal in various ways, for example using a resettable flip-flop.

In particular, the division of the control signal 3 (which has a length of P=N+M bits) into most significant and least significant bits for the purpose of controlling various delay times in order to set the pulse width may also be coded in an alternative manner.

However, the inventive pulse width modulator can always be used at various clock frequencies and is robust toward fluctuations in the operating temperature, supply voltage or production parameters.

List of Reference Symbols

clk Clock signal
P, M, N control bits
Z Counter
D Digital pulse width modulator unit
K1, K2 comparators
R, S set input, reset input
FF flip-flop
Z1-Z4 Intermediate signals
A Pulse width modulated output signal
T Clock period
Δt Delay time
1 High-resolution pulse width modulator
3 Digital control signal
5 Programmable delay path
6 Control logic unit
7 Adjusting signal
8 Logic circuit
12 Multiplexer
13 Phase detector
17 Filter
2, 4, 10, Inputs
14, 15,
21, 27
9, 11, 16 Outputs
31-37, 41-48 Delay stages
61 Delay locked loop

1-21. (canceled)

22. A high-resolution digital pulse width modulator circuit arrangement comprising:
a) a digital pulse width modulator operable to receive a clock signal having a clock period, the digital pulse width modulator further operable to receive a first quantity of bits of a digital control signal, the digital control signal of a bit length comprising the first quantity of bits and a second quantity of bits, the digital pulse width modulator further operable to generate a pulse width modulated first intermediate signal, wherein the pulse width of the first intermediate signal is an integral multiple of the clock period;
b) a programmable signal delay path operable to delay the first intermediate signal by a programmable signal delay time on the basis of the second quantity of bits of the digital control signal, the programmable signal delay path further operable to output a pulse width modulated second intermediate signal, wherein the programmable signal delay time and the clock period have a fixed ratio; and
c) a logic circuit operable to logically combine the first intermediate signal and the second intermediate signal to form a pulse width modulated output signal.

23. The pulse width modulator circuit arrangement of claim 22 wherein the logic circuit is an OR gate.

24. The pulse width modulator circuit arrangement of claim 22 wherein a control logic unit also receives the clock signal and the control logic unit provides the signal delay path with at least one adjusting signal when the digital control signal is provided to the signal delay path.

25. The pulse width modulator circuit arrangement of claim 24 wherein the signal delay path comprises a plurality of controllable delay stages.

26. The pulse width modulator circuit arrangement of claim 25 wherein the at least one adjusting signal controls the plurality of controllable delay stages.

27. The pulse width modulator circuit arrangement of claim 25 wherein an integral multiple of a signal delay time of at least one of the plurality of controllable delay stages is equal to the clock period of the clock signal.

28. The pulse width modulator circuit arrangement as claimed in claim 25 wherein the sum of the signal delay times of the plurality of controllable delay stages is equal to the duration of the clock period.

29. The pulse width modulator circuit arrangement as claimed in claim 25 wherein the plurality of controllable delay stages are connected in series, and the second intermediate signal is tapped off between the plurality of controllable delay stages.

30. The pulse width modulator circuit arrangement as claimed in claim 29 wherein the second intermediate signal comprises a plurality of second intermediate signals, and the signal delay path comprises a multiplexer operable to select one of the plurality of second intermediate signals for delivery to the logic circuit on the basis of the second quantity of bits of the digital control signal.

31. The pulse width modulator circuit arrangement of claim 25 wherein exactly 2^{N}−1 controllable delay stages are provided, wherein N equals the second quantity of bits of the digital control signal.

32. The pulse width modulator circuit arrangement of claim 24 wherein the control logic unit comprises a delay locked loop.

33. The pulse width modulator circuit arrangement of claim 32 wherein the delay locked loop comprises 2^{N} controllable delay stages which are connected in series, wherein N equals the second quantity of bits of the digital control signal.

34. The pulse width modulator circuit arrangement of claim 33 wherein the plurality of controllable delay stages are of identical design.

35. The pulse width modulator circuit arrangement of claim 33 wherein the delay locked loop comprises a phase detector operable to compare the clock signal with the clock signal that has passed through all of the delay stages in the delay locked loop and output a comparison result signal.

36. The pulse width modulator circuit arrangement of claim 35 wherein the delay lock loop further comprises a digital filter operable to filter the comparison result signal and provide the delay stages in the delay locked loop with the at least one adjusting signal.

37. The pulse width modulator circuit arrangement of claim 36 wherein the digital filter is a counter.

38. The pulse width modulator circuit arrangement of claim 24 wherein the control logic unit comprises a phase locked loop.

39. The pulse width modulator circuit arrangement of claim 25 wherein the plurality of controllable delay stages comprise controllable inverter chains.

40. The pulse width modulator circuit arrangement of claim 22 wherein the pulse width modulator is of integrated design.

41. The pulse width modulator circuit arrangement of claim 22 wherein the bit length of the digital control signal is equal to P and P=M+N, wherein M equals the first quantity of bits of the digital control signal and N equals the second quantity of bits of the digital control signal.

42. A method for generating a high-resolution pulse width modulated signal, the method comprising the steps of:
a) receiving a clock signal having a clock period T;
b) generating a pulse width modulated first intermediate signal, wherein the pulse width of the first intermediate signal is a multiple of the clock period T;
c) determining a signal delay time Δt so that a multiple of the signal delay time Δt is equal to the clock period T;
d) generating at least one second intermediate signal by delaying the first intermediate signal by the signal delay time Δt; and
e) logically combining the first intermediate signal with the second intermediate signal in order to generate the high-resolution pulse width modulated signal.
